(19) United States
(12) Patent Application Publication
(10) Pub. No.: US 2009/0045458 A1
(43) Pub. Date: Feb. 19, 2009

(54) MOS TRANSISTORS FOR THIN SOI INTEGRATION AND METHODS FOR FABRICATING THE SAME

(75) Inventors: John A. IACOPONI, Wappingers Falls, NY (US); Kingsuk MAITRA, Yorktown Heights, NY (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 11/838,982

(22) Filed: Aug. 15, 2007

(51) Int. Cl. H01L 29/786; H01L 21/3205; H01L 21/336

(52) U.S. Cl. 257/330; 438/156; 438/589; 257/E21.41; 257/E29.262; 257/E21.294

(57) ABSTRACT

MOS transistors for thin SOI integration and methods for fabricating such MOS transistors are provided. One exemplary method includes the steps of providing a silicon layer overlying a buried insulating layer and epitaxially growing a silicon-comprising material layer overlying the silicon layer. A trench is etched within the silicon-comprising material layer and exposing the silicon layer. An MOS transistor gate stack is formed within the trench. The MOS transistor gate stack comprises a gate insulator and a gate electrode. Ions of a conductivity-determining type are implanted within the silicon-comprising material layer using the gate stack as an implantation mask.

### FIELD OF THE INVENTION

The present invention generally relates to MOS transistors and methods for fabricating MOS transistors, and more particularly relates to MOS transistors for thin SOI integration and methods for fabricating MOS transistors for thin SOI integration.

### BACKGROUND OF THE INVENTION

The majority of present day integrated circuits (ICs) are implemented by using a plurality of interconnected field effect transistors (FETs), also called metal oxide semiconductor field effect transistors (MOSFETs or MOS transistors). The ICs are usually formed using both P-channel FETs (PMOS transistors or PFETs) and N-channel FETs (NMOS transistors or NFETs) and the IC is then referred to as a complementary MOS or CMOS circuit. Certain improvements in performance of MOS ICs can be realized by forming the MOS transistors in and/or on a thin silicon-on-insulator (SOI) layer, that is, a thin layer of silicon that overlies a buried insulator layer. Such SOI MOS transistors, for example, exhibit lower junction capacitance and hence can operate at higher speeds.

As CMOS technology advances, the thickness of the SOI layer is decreasing to further enhance MOS device performance. Conventional methods for fabricating an MOS transistor on an SOI layer include the formation of a gate insulating layer on the SOI layer followed by the deposition of a gate electrode material layer. The gate insulating layer and the gate electrode material layer then are etched to form a gate stack comprising a gate insulator and an overlying gate electrode on the SOI layer. However, formation of the gate stack utilizes aggressive etching steps that can result in excessive consumption of the underlying SOI layer. If the etching is too aggressive, the SOI layer can be etched through to the underlying buried insulating layer and the device is destroyed. Even if not etched through to the buried insulating layer, the SOI layer may be etched so that it is too thin for further device processing.

Accordingly, it is desirable to provide methods for fabricating MOS transistors wherein the methods do not result in over-etching of an underlying SOI layer. In addition, it is desirable to provide MOS transistors fabricated from such methods. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method for fabricating an MOS transistor in accordance with an exemplary embodiment of the present invention is provided. The method comprises the steps of providing a silicon layer overlying a buried insulating layer and epitaxially growing a silicon-comprising material layer overlying the silicon layer. A trench is etched within the silicon-comprising material layer and exposing the silicon layer. An MOS transistor gate stack is formed within the trench. The MOS transistor gate stack comprises a gate insulator and a gate electrode. Ions of a conductivity-determining type are implanted within the silicon-comprising material layer using the MOS transistor gate stack as an implantation mask.

A method for fabricating an MOS transistor in accordance with another exemplary embodiment of the present invention is provided. The method comprises the steps of epitaxially growing a strained silicon-comprising material layer on an SOI layer and etching a trench within the strained silicon-comprising material layer. A high dielectric constant material is deposited within the trench and a layer of work function material is formed overlying the high dielectric constant material. A surface of the strained silicon-comprising material layer is exposed and an impurity-doped region is formed within the strained silicon-comprising material layer.

An MOS structure in accordance with an exemplary embodiment of the present invention is provided. The MOS transistor comprises an SOI layer and an epitaxially-grown silicon-comprising material layer disposed on the SOI layer. The epitaxially-grown silicon-comprising material layer comprises a first impurity-doped region, a second impurity-doped region, and a trench disposed between the first and second impurity-doped regions. A gate insulator is disposed within the trench overlying the SOI layer and a gate electrode is disposed within the trench overlying the gate insulator.

### BRIEF DESCRIPTION OF THE DRAWINGS

The present invention will hereinafter be described in conjunction with the following drawing figures, wherein like numerals denote like elements, and wherein:

FIGS. 1-7 illustrate, in cross section, a method for fabricating an MOS transistor for thin SOI integration, in accordance with an exemplary embodiment of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

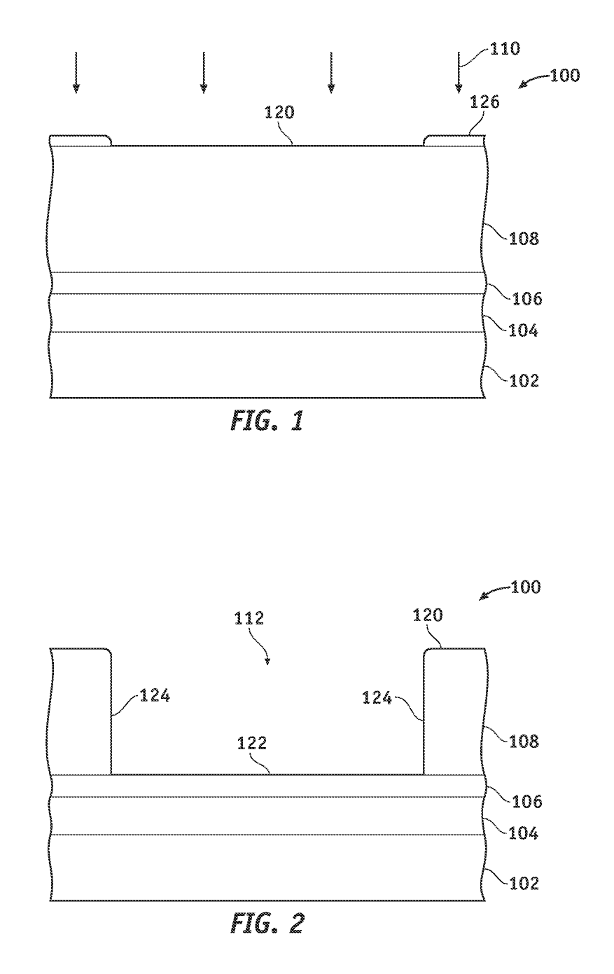

FIGS. 1-7 illustrate, in cross-section, an MOS transistor 100 and a method for fabricating MOS transistor 100 in accordance with an exemplary embodiment of the present invention. Although the term “MOS transistor” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate. The MOS transistor can be N-channel MOS transistor (NMOS transistor) or a P-channel MOS transistor (PMOS transistor). Various steps in the manufacture of MOS components are well known and so, in the interest of brevity, many conventional steps will only be mentioned briefly herein or will be omitted entirely without providing the well known process details.

Referring to FIG. 1, the method in accordance with one embodiment of the invention begins with an SOI layer 106 of an SOI structure having an insulating layer 104 disposed on a silicon substrate 102. As used herein, the terms “SOI layer” and “silicon substrate” will be used to encompass the relatively pure or lightly impurity-doped monocrystalline silicon materials typically used in the semiconductor industry as well as silicon admixed with other elements such as germanium, carbon, and the like to form substantially monocrystalline semiconductor material. The SOI layer may have any thickness desired for a particular device design or application. For example, SOI layer 106 may have a thickness of about 5 to about 6 nm, such as when subsequently-formed MOS transistor 100 will be used in a high-power logic device. However, it will be appreciated that SOI layer 106 may have a thickness less than or greater than about 5 to 6 nm as required for device design. SOI layer 106 can be doped with an impurity dopant of a conductivity-determining type. For example, if transistor 100 is an NMOS transistor, SOI layer 102 is doped with boron ions. If the transistor is a PMOS transistor, SOI layer 102 is doped with arsenic or phosphorous ions. Alternatively, when, for example, MOS transistor 100 comprises a high dielectric constant gate insulator, as described in more detail below, it may be preferable to leave SOI layer 102 undoped. The buried insulating layer 104 can be, for example, silicon dioxide.

A silicon-comprising material layer 108 is epitaxially grown on the SOI layer 106. The epitaxial silicon-comprising material layer 108 can be grown by the reduction of silane (SiH₄) or dichlorosilane (SiH₂Cl₂) in the presence of HCl. In an exemplary embodiment of the invention, the epitaxial silicon-comprising material layer 108 may be doped with conductivity-determining type ions while being grown, that is, it may be doped “in-situ”. Alternatively, as illustrated, the epitaxial silicon-comprising material layer 108 may be doped after having been grown. For example, layer 108 may be doped by ion implantation of dopant ions, illustrated by arrows 110, into a surface 120 and subsequent thermal annealing to drive the dopants through layer 108. For an NMOS transistor, the epitaxial silicon-comprising material layer 108 is doped by any N-type conductivity-determining ion such as arsenic ions, phosphorus ions, and/or antimony ions. For a PMOS transistor, epitaxial silicon-comprising material layer 108 preferably is doped by implanting boron ions. In another exemplary embodiment of the invention, the epitaxial silicon-comprising material layer 108 also may be grown to include a strain-inducing dopant such as, for example, germanium or carbon, the concentration of which may be controlled to obtain a desired strain within layer 108. The epitaxial silicon-comprising material layer 108 can be grown to any thickness desired for a particular device design or application. In an exemplary embodiment, the epitaxial silicon-comprising material layer 108 is grown to a thickness in the range of about 30 nm to about 50 nm. A photoresist 126 is applied to the surface 120 of epitaxial silicon-comprising material layer 108 and is patterned to expose a portion of epitaxial silicon-comprising material layer 108.

Referring to FIG. 2, the exposed portion of epitaxial silicon-comprising material layer 108 is etched to form a trench 112 that extends from surface 120 through layer 108 to expose SOI layer 106. The trench is formed with sidewalls 124 and a bottom surface 122 that is also a top surface of SOI layer 106. The epitaxial silicon-comprising material layer 108 is anisotropically etched, for example, by reactive ion etching (RIE) using an HBr/O₂ and Cl chemistry. In one exemplary embodiment, after formation of trench 112, the etching may be continued to further thin the SOI layer. The photoresist 126 then is removed.

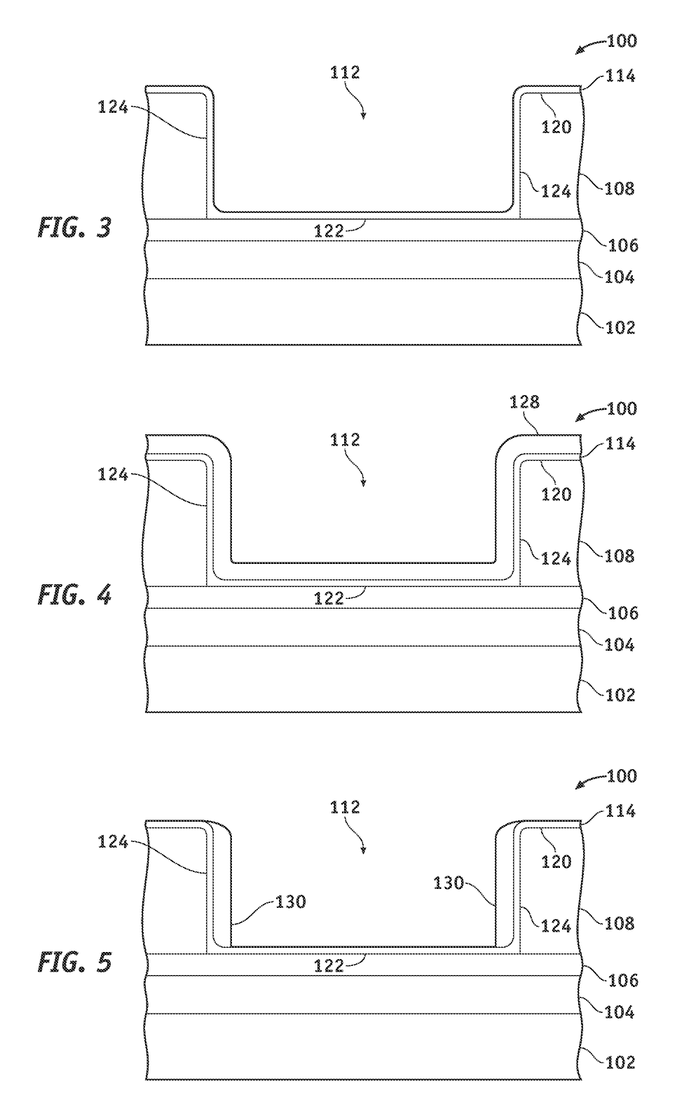

The method continues in accordance with an exemplary embodiment of the invention with the formation of an interfacial layer 114 along the sidewalls 124 and bottom surface 122 of trench 112, as illustrated in FIG. 3. The interfacial layer 114 can be a layer of thermally grown silicon dioxide or, alternatively (as illustrated), a deposited insulator such as a silicon oxide, silicon nitride, or the like. Deposited insulators can be deposited, for example, by chemical vapor deposition (CVD), low pressure chemical vapor deposition (LPCVD), or plasma enhanced chemical vapor deposition (PECVD). Interfacial layer 114 preferably has a thickness of no greater than about 10 nm, although the actual thickness can be determined based on the application of the transistor in the circuit being implemented. In one exemplary embodiment, the interfacial layer 114 has a thickness of about 0.5 nm.

Referring to FIG. 4, a blanket layer 128 of dielectric material having a different etching characteristic than interfacial layer 114 is deposited overlying interfacial layer 114. For example, if interfacial layer 114 is silicon dioxide, layer 128 can be silicon nitride or silicon oxynitride. Using interfacial layer 114 as an etch stop layer, the layer 128 of dielectric material is subsequently anisotropically etched, for example by RIE using, for example, a CHF₃, CF₄, or SF₆ chemistry, to form spacers 130 about sidewalls 124, as illustrated in FIG. 5. As with the interfacial layer 114, the spacers 130 are formed with a thickness that is determined based on the application of the transistor 100 in the circuit being implemented. In particular, the spacers 130 have a thickness that minimizes parasitic capacitance between a source/drain region subsequently formed in layer 108, as described in more detail below, and a gate electrode subsequently formed within trench 112, also as described in more detail below. In one exemplary embodiment, the spacers 130 have a thickness of about 10 to about 20 nm.

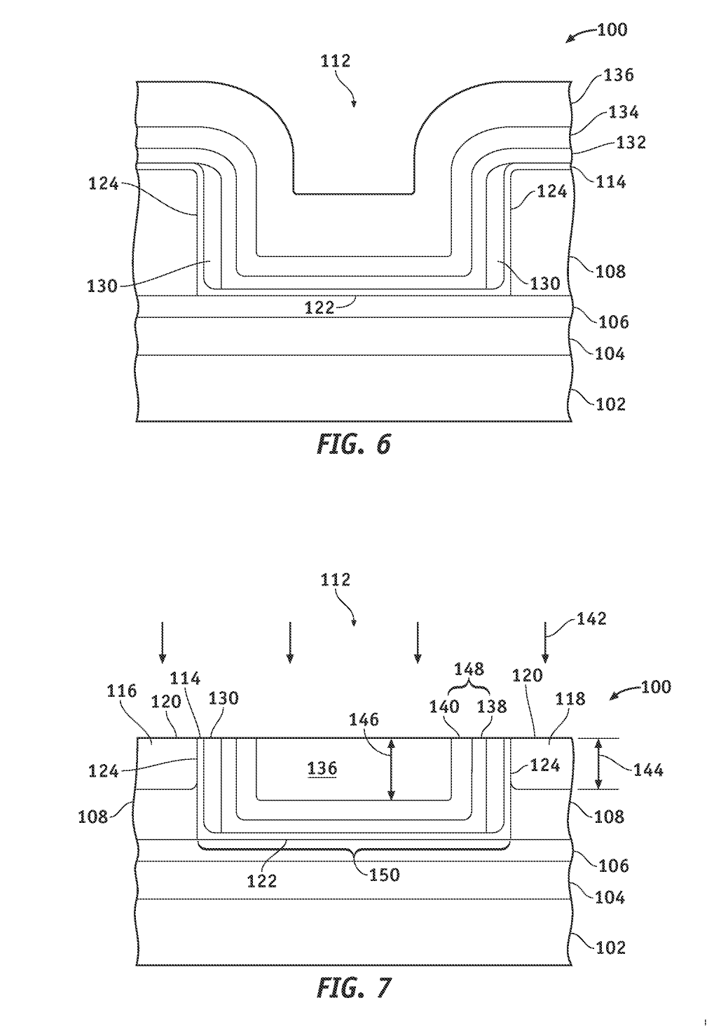

Referring to FIG. 6, a layer 132 of gate insulator material is conformally deposited within trench 112 and overlying spacers 130 and exposed interfacial layer 114. The gate insulator material can be an insulator such as a silicon oxide, silicon nitride, or the like. In a preferred embodiment of the invention, the gate insulator material is an insulating material having a high dielectric constant (“high-k material”). As used herein, the term “high-k material” or “high dielectric constant material” refers to a dielectric material having a dielectric constant greater than that of SiO₂, which is approximately 3.9. The high-k material can be deposited in known manner by, for example, CVD, LPCVD, PECVD, semi-atmospheric chemical vapor deposition (SACVD), or atomic layer deposition (ALD). Examples of high-k materials that can be used to form MOS transistor 100 include, but are not limited to, binary metal oxides including aluminum oxide (Al₂O₃), zirconium oxide (ZrO₂), hafnium oxide (HfO₂), lanthanum oxide (La₂O₃), yttrium oxide (Y₂O₃), titanium oxide (TiO₂), as well as their silicates and aluminates; metal oxynitrides including aluminum oxynitride (AlON), zirconium oxynitride (ZrON), hafnium oxynitride (HfON), lanthanum oxynitride (LaON), yttrium oxynitride (YON), as well as their silicates and aluminates; perovskite-type oxides including a titanate system material such as barium titanate, strontium titanate, barium strontium titanate (BST), lead titanate, lead zirconate titanate, lead lanthanum zirconate titanate, barium lanthanum titanate, barium zirconium titanate; a niobate or tantalite system material such as lead magnesium niobate, lithium niobate, lithium tantalate, potassium niobate, strontium aluminum tantalate and potassium tantalum niobate; a tungsten-bronze system material such as barium strontium niobate, lead barium niobate, barium titanium niobate; and a bi-layered perovskite system material such as strontium bismuth tantalate and bismuth titanate; and combinations thereof. Gate insulator material layer 132 has a thickness that is determined based on the application of the transistor in the circuit being implemented. For example, if MOS transistor 100 will be used in a high performance logic device, gate insulator material layer 132 may have a thickness of about 1.5 to about 2.0 nm.

A layer 134 of gate electrode material is conformally deposited overlying the gate insulating material layer 132. In one exemplary embodiment of the invention, the gate electrode material comprises a metal such as, for example, titanium nitride, or a metal-comprising material such as a metal silicide. In another exemplary embodiment, the gate electrode material comprises polycrystalline silicon. The material selected for layer 134 must have the proper work function to provide the proper threshold voltage of the MOS transistor 100. The material may be formed by itself or with appropriate impurity doping that can set the necessary threshold voltage of the transistor. Gate electrode material layer 134 has a thickness that is determined based on the application of the transistor in the circuit being implemented. In one exemplary embodiment, the gate electrode material layer 134 has a thickness of about 5 nm to about 15 nm.

In accordance with an exemplary embodiment of the present invention, a capping layer 136 is deposited overlying gate electrode material layer 134. In accordance with one exemplary embodiment, such as when gate electrode material layer 134 is formed of a metal or metal silicide, the capping layer is formed of polycrystalline silicon. The polycrystalline silicon can be deposited by LPCVD by the hydrogen reduction of silane. The capping layer preferably fills trench 112 but can be deposited to a lesser thickness if desired. In one exemplary embodiment, the capping layer has a thickness in the range of about 50 to about 70 nm. It will be appreciated that if the gate electrode material layer 134 is formed of polycrystalline silicon, the step of forming capping layer 136 can be eliminated.

Referring to FIG. 7, after deposition of gate electrode material layer 134 and capping layer 136, if present, any excess material overlying surface 120 of epitaxial silicon-comprising material layer 108 is removed, thus forming a gate stack 148 with a gate insulator 138 and an overlying gate electrode 140 disposed within trench 112. The material can be removed by a suitable etch or, preferably, by chemical mechanical planarization (CMP). After surface 120 of layer 108 is exposed, two highly-doped spaced-apart source/drain regions 116 and 118 can be formed within layer 108 with trench 112 disposed therebetween. The source/drain regions 116 and 118 are formed by appropriately impurity doping epitaxial silicon-comprising material layer 108 in known manner, for example, by ion implantation of dopant ions, illustrated by arrows 142, and subsequent thermal annealing. By using the gate stack 148, spacers 130, interfacial layer 114, and capping layer 136, if present, as an implantation mask, the source/drain regions 116, 118 are self-aligned thereto. The time and temperature of the thermal annealing are determined by the desired depth of the source/drain regions. In a preferred embodiment of the invention, the source/drain regions 116 and 118 extend through layer 108 to a depth, indicated by double-headed arrow 144, which is about a depth, indicated by double-headed arrow 146, of capping layer 136. During the formation of the source/drain regions, polycrystalline silicon capping layer 136 also is impurity doped. Because deep highly-doped source/drain regions 116, 118 extend through a portion of epitaxial silicon-comprising material layer 108 and the remaining lesser-doped portions of layer 108 serve as source/drain extensions, a channel region 150 is created through SOI layer 106 beneath the gate stack 148 between the doped layer 108. Thus, when a potential is applied to the gate electrode 140, such as through capping layer 136, the channel region 150 is inverted for operation of MOS transistor 100.

Accordingly, the gate stack 148 of MOS transistor 100 is formed overlying SOI layer 106 within trench 112 and between two source/drain regions 116, 118 of epitaxial silicon-comprising material layer 108. In this regard, the etch chemistry to which SOI layer 106 is exposed during formation of MOS transistor 100 is not an aggressive etch used to form gate stack 148 but, rather, is a significantly less aggressive etch used to form trench 112 within epitaxial silicon-comprising material layer 108. This less aggressive etch can be more easily and efficiently controlled to thus minimize consumption of SOI layer 106 during the etching process.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for fabricating an MOS transistor, the method comprising the steps of:
providing a silicon layer overlying a buried insulating layer;
epitaxially growing a silicon-comprising material layer overlying the silicon layer;
etching a trench within the silicon-comprising material layer and exposing the silicon layer;
fabricating an MOS transistor gate stack within the trench, wherein the MOS transistor gate stack comprises a gate insulator and a gate electrode; and
implanting ions of a conductivity-determining type within the silicon-comprising material layer using the MOS transistor gate stack as an implantation mask.

2. The method of claim 1, wherein the step of providing a silicon layer comprises the step of providing a silicon layer having a thickness of no greater than about 6 nm.

3. The method of claim 1, wherein the step of epitaxially growing a silicon-comprising material layer comprises the step of epitaxially growing the silicon-comprising material layer in the presence of a strain-inducing dopant.

4. The method of claim 1, wherein the step of epitaxially growing a silicon-comprising material layer comprises the step of epitaxially growing the silicon-comprising material layer in the presence of a conductivity-determining type dopant.

5. The method of claim 1, wherein the step of fabricating an MOS transistor gate stack comprises the steps of:
depositing a dielectric material within the trench and overlying the silicon layer; and
depositing a work function material overlying the dielectric material.

6. The method of claim 5, wherein the step of depositing a dielectric material comprises the step of depositing a dielectric material having a high dielectric constant.

7. The method of claim 5, further comprising, after the step of depositing a work function material, the step of removing any excess work function material and dielectric material disposed outside the trench and overlying the silicon-comprising material layer to expose the silicon-comprising material layer.

8. The method of claim 1, further comprising, after the step of etching a trench, the step of forming an interfacial layer within the trench.

9. The method of claim 8, wherein the step of forming an interfacial layer comprises the step of forming a silicon oxide layer within the trench.

10. The method of claim 1, further comprising, after the step of etching a trench, the step of forming spacers about sidewalls of the trench.

11. The method of claim 9, wherein the step of forming spacers comprises the step of forming silicon nitride spacers.

12. The method of claim 1, further comprising, after the step of depositing a work function material, the step of depositing a capping layer.

13. The method of claim 12, wherein the step of depositing a capping layer comprises the step of depositing a polycrystalline silicon layer.

14. A method for fabricating an MOS transistor, the method comprising the steps of:
epitaxially growing a strained silicon-comprising material layer on an SOI layer;
etching a trench within the strained silicon-comprising material layer;
depositing a high dielectric constant material within the trench;
forming a layer of work function material overlying the high dielectric constant material;
exposing a surface of the strained silicon-comprising material layer; and
forming an impurity-doped region within the strained silicon-comprising material layer.

15. The method of claim 14, further comprising, after the step of etching a trench, the step of forming an interfacial layer within the trench.

16. The method of claim 15, further comprising, after the step of forming an interfacial layer, the steps of:
depositing a spacer-forming material layer within the trench; and
anisotropically etching the spacer-forming material layer to form spacers within the trench.

17. The method of claim 16, wherein the step of forming an interfacial layer comprises the step of forming a silicon oxide layer and the step of depositing a spacer-forming material layer comprises the step of depositing a silicon nitride or silicon oxynitride layer.

18. The method of claim 14, further comprising, after the step of forming a layer of work function material, the step of fabricating a capping layer overlying the layer of work function material.

19. The method of claim 18, wherein the step of forming a layer of work function material comprises the step of forming a layer of work function metal and the step of fabricating a capping layer comprises the step of fabricating a polycrystalline silicon capping layer.

20. An MOS transistor comprising:
an SOI layer;
an epitaxially-grown silicon-comprising material layer disposed on the SOI layer, wherein the epitaxially-grown silicon-comprising material layer comprises a first impurity-doped region, a second impurity-doped region, and a trench disposed between the first and second impurity-doped regions;
a gate insulator disposed within the trench overlying the SOI layer; and
a gate electrode disposed within the trench overlying the gate insulator.
